(19) United States
(12) Patent Application Publication
(10) Pub. No.: US 2012/0031338 A1
(43) Pub. Date: Feb. 9, 2012

(54) SUSCEPTOR AND APPARATUS FOR CVD WITH THE SUSCEPTOR

(75) Inventor: Won Shin LEE, Suwon-si (KR)

(73) Assignee: SAMSUNG LED CO., LTD., Suwon-si (KR)

(21) Appl. No.: 13/197,366

(22) Filed: Aug. 3, 2011

(30) Foreign Application Priority Data
Aug. 9, 2010 (KR) 10-2010-0076367

(51) Int. Cl. C23C 16/458; C23C 16/455

(52) U.S. Cl. 118/724; 118/728; 118/730

(57) ABSTRACT

A susceptor and an apparatus for chemical vapor deposition (CVD) are provided. The susceptor includes a main body configured to include a mounting unit having an uneven plane, and a substrate supporting unit configured to be seated on the mounting unit. A bottom surface of the substrate supporting unit has a shape corresponding to a shape of the mounting unit, and the mounting unit includes a gas discharge hole to discharge gas to the substrate supporting unit. Accordingly, accurate positioning of the substrate supporting unit may not be required when the substrate supporting unit is being returned. Also, the vapor deposition may be stably performed.

### CROSS-REFERENCE TO RELATED APPLICATION

This application claims the benefit of Korean Patent Application No. 10-2010-0076367, filed on Aug. 9, 2010, in the Korean Intellectual Property Office, the of which is incorporated herein by reference.

### BACKGROUND

1. Field

Example embodiments of the following description relate to a susceptor and a chemical vapor deposition (CVD) apparatus with the susceptor.

2. Description of the Related Art

A light emitting diode (LED) is a semiconductor device that converts an electrical current into light. Manufacturing processes for the LED includes an epiwafer manufacturing process, a chip manufacturing process, a packaging process, and a modularizing process.

The epiwafer manufacturing process manufactures an epiwafer by growing a GaN-based crystal on a substrate using a metal organic chemical vapor deposition (MOCVD) apparatus.

Generally, the substrate is supported by a satellite disc mounted to a susceptor of the MOCVD apparatus.

When separated from the susceptor, the substrate may be lifted by a robot arm. However, when the robot arm directly lifts the substrate, the substrate may be damaged due to a sudden temperature change. Therefore, the substrate is usually transferred along with the satellite disc.

Afterwards, the satellite disc is separated from the substrate and returned to the susceptor. Here, the satellite disc in being returned to the susceptor needs to be seated in a correct position of the susceptor.

### SUMMARY

According to example embodiments, there may be provided a susceptor for a chemical vapor deposition (CVD) apparatus capable of efficiently positioning a substrate supporting unit, such as a satellite disc, being returned to the susceptor.

According to example embodiments, there may be also be provided a susceptor for a CVD apparatus capable of positioning a substrate supporting unit being returned to the susceptor, without using a pin.

The foregoing and/or other aspects are achieved by providing a susceptor including a main body configured to include a mounting unit having an uneven plane; and a substrate supporting unit configured to be seated on the mounting unit, wherein a bottom surface of the substrate supporting unit has a shape corresponding to a shape of the mounting unit, and the mounting unit includes a gas discharge hole, to discharge gas from the substrate supporting unit.

The foregoing and/or other aspects are achieved by providing an apparatus for CVD, including a reaction chamber configured to be supplied with a reaction gas; and a susceptor configured to include a main body, rotatively mounted to the reaction chamber, and a substrate supporting unit, removably connected to the main body, wherein the main body is provided with a mounting unit including an inclined surface, and the substrate supporting unit is provided with an inclined surface corresponding to the inclined surface of the mounting unit.

Additional aspects, features, and/or advantages of example embodiments will be set forth in part in the description which follows and, in part, will be apparent from the description, or may be learned by practice of the disclosure.

### BRIEF DESCRIPTION OF THE DRAWINGS

These and/or other aspects and advantages will become apparent and more readily appreciated from the following description of the example embodiments, taken in conjunction with the accompanying drawings of which:

FIG. 1 illustrates a plan view of a susceptor for a chemical vapor deposition (CVD) apparatus, according to example embodiments;

FIG. 2 illustrates a sectional view of the susceptor for the CVD apparatus;

FIG. 3 illustrates a sectional view of the susceptor shown in FIG. 2, where a substrate supporting unit is separated;

FIG. 4 illustrates a bottom perspective view of the substrate supporting unit;

FIG. 5 illustrates a sectional view of a susceptor for a CVD apparatus, according to other example embodiments;

FIG. 6 illustrates a sectional view of the susceptor shown in FIG. 5, where a substrate supporting unit is separated; and

FIG. 7 illustrates a bottom perspective view of the substrate supporting unit;

### DETAILED DESCRIPTION

Reference will now be made in detail to example embodiments, examples of which are illustrated in the accompanying drawings, wherein like reference numerals refer to the like elements throughout. Example embodiments are described below to explain the present disclosure by referring to the figures.

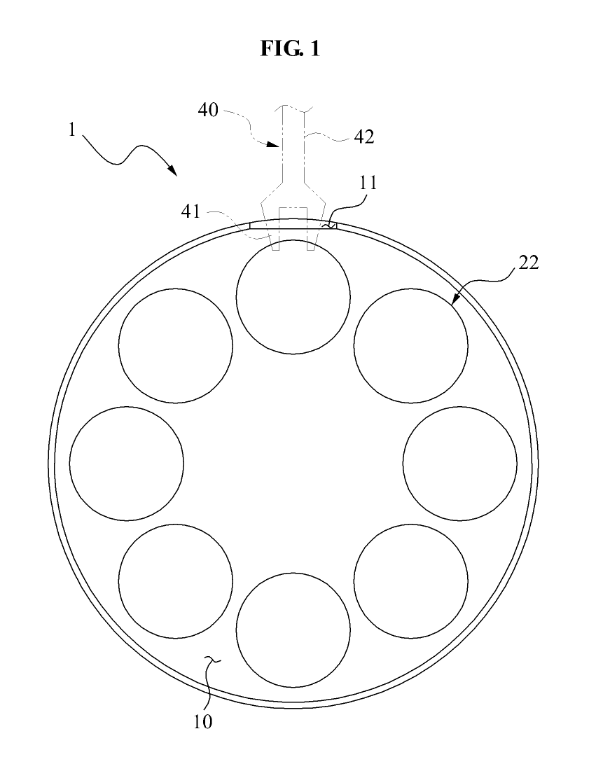

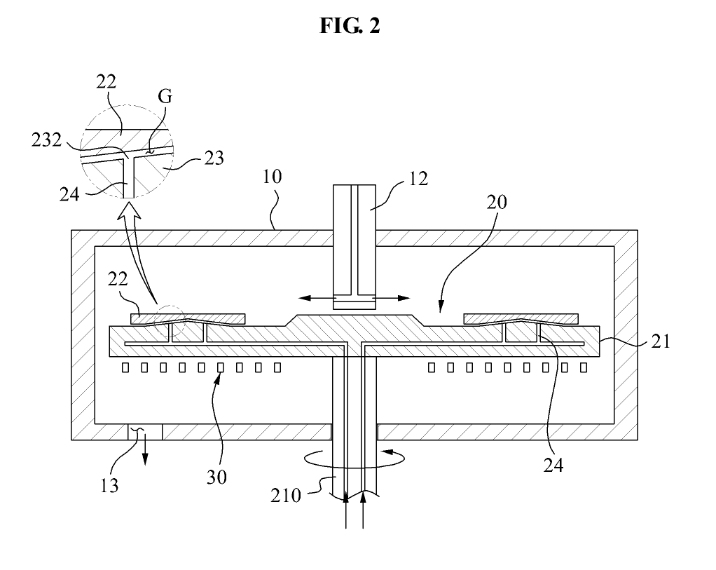

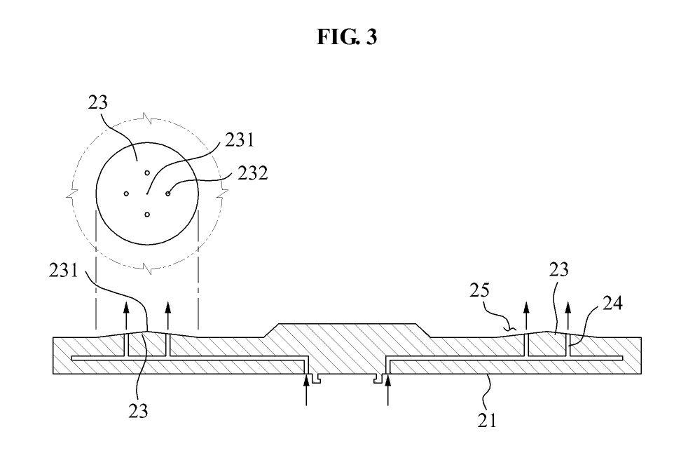

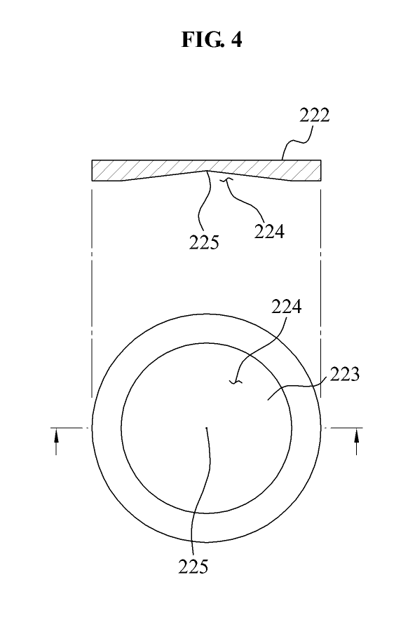

FIG. 1 illustrates a plan view of a susceptor 20 for a chemical vapor deposition (CVD) apparatus 1, according to example embodiments. FIG. 2 illustrates a sectional view of the susceptor 20 for the CVD apparatus 1. FIG. 3 illustrates a sectional view of the susceptor 20 shown in FIG. 2, where a substrate supporting unit 22 is separated. FIG. 4 illustrates a bottom perspective view of the substrate supporting unit 22.

Referring to FIGS. 1 through 4, the CVD apparatus 1 may include a reaction chamber 10 to supply a space where a chemical reaction is performed, the susceptor 20 to mount at least one substrate (not shown), a heat source 30 to heat the susceptor 20, and a transfer unit 40 to transfer the substrate supporting unit 22.

The reaction chamber 10 includes an inlet 11 to allow passage of the substrate supporting unit 22, a reaction gas supply unit 12 to supply a reaction gas, and an outlet 13 to discharge a waste gas remaining after the chemical reaction between the reaction gas and the substrate.

The reaction chamber 10 may be a cylindrical structure that supplies an inner space of a predetermined size. In addition, the reaction chamber 10 may be made of a metal which is highly abrasion-resistant and corrosion-resistant. An insulating material may be provided to an inner circumference of the reaction chamber 10 so that the reaction chamber 10 is resistant to a high temperature.

The reaction gas supply unit 12 may be disposed at an upper end of the reaction chamber 10. The reaction gas supply unit 12 may extend downward from the upper end of the reaction chamber 10. A lower end of the reaction gas supply unit 12 may extend up to a position near a center of a main body 21 of the susceptor 20.

A pipe may be provided inside the reaction gas supply unit 12 to allow the reaction gas to flow. The reaction gas may include Mo, NH₃, H₂, N₂, and the like. The reaction gas may flow in a vertical direction within the reaction gas supply unit 12 and bend to a horizontal direction at the lower end of the reaction gas supply unit 12. Accordingly, the reaction gas may be discharged from the reaction gas supply unit 12 in the horizontal direction and then flow in the horizontal direction into an upper portion of the main body 21.

As the reaction gas flowing in through the reaction gas supply unit 12 reacts with the substrate, an epitaxial layer may be vapor-deposited and grown on an upper surface of the substrate.

The susceptor 20 may include the main body 21, and the substrate supporting unit 22, removably connected to the main body 21.

The main body 21 may be composed of graphite coated with carbon or silicon carbide (SiC). The main body 21 may have a disc shape to be easily rotated in the reaction chamber 10.

An upper surface of the main body 21, may include a mounting unit 23 on which the substrate supporting unit 22 is seated. A plurality of the mounting units 23 may be arranged co-planarly at uniform intervals in a circumferential direction with respect to a center of the main body 21.

The mounting unit 23 may include an uneven surface to minimize escape of the substrate supporting unit 22 from the main body 21 during a return of the substrate supporting unit 22. More specifically, the mounting unit 23 may protrude from the upper surface of the main body 21. For example, the mounting unit 23 may have a conical shape. Accordingly, a pointed tip 231 may be formed in a center of the mounting unit 23, while an inclined surface is formed around the pointed tip 231. The inclined surface may be inclined downward in a direction from the pointed tip 231 to a periphery.

The mounting unit 23 may include a gas discharge hole 232 adapted to discharge gas. The gas discharge hole 232 may be disposed on the inclined surface of the mounting unit 23. The gas discharge hole 232 may be at least three in number. Through the gas discharge hole 232, gas may be discharged in an upward direction. Therefore, the gas may support the substrate supporting unit 22 vertically. The gas may be diverted by a bottom surface of the substrate supporting unit 22 and therefore discharged to a side of the substrate supporting unit 22. Therefore, the substrate supporting unit 22 may be separated by a predetermined interval from the main body 21. That is, a predetermined gap G is formed between the substrate supporting unit 22 and the main body 21. The gap G may be constantly maintained because a weight of the substrate supporting unit 22 and a supporting force of the gas supporting the substrate supporting unit 22 are balanced.

Exemplarily, the gas discharged through the gas discharge hole 232 does not affect the crystal growth on the substrate. Considering this, the gas may be nitrogen or hydrogen.

A rotational shaft 210 may be connected to a lower surface of the main body 21. A driving source such as a motor may be connected to the rotational shaft 210. The main body 21 may be rotated integrally with the rotational shaft 210.

The main body 21 may include a gas supply pipe 24 disposed therein to supply the gas being discharged through the gas discharge hole 232. The gas supply pipe 24 may supply the gas from an external gas source (not shown) provided at the outside of the reaction chamber 10 to the gas discharge hole 232. As shown in FIG. 2, the gas supply pipe 24 may be connected to the external gas source through the rotational shaft 210 to prevent twist of the gas supply pipe 24 caused by rotation of the main body 21.

The substrate supporting unit 22 may be seated on the mounting unit 23. In the same manner as the main body 21, the substrate supporting unit 22 may be made of carbon coated with SiC. In addition, the substrate supporting unit 22 may have a disc shape to be easily rotated on the main body 21.

The substrate may be seated on an upper surface 222 of the substrate supporting unit 22. The upper surface 222 may be plane. Materials of the substrate are not specifically defined. Therefore, a dielectric substrate made of sapphire or spinel (MgAl₂O₄), a semiconductor substrate made of SiC, Si, ZnO, GaAs, or GaN, and a conductive substrate may be used as the substrate. However, it is exemplary to use a sapphire substrate when manufacturing a horizontal semiconductor LED as in the present embodiments. According to a chemical reaction between the substrate and the reaction gas, a GaN-based crystal may grow on the substrate.

The substrate supporting unit 22 may be rotated on the main body 21 by viscosity of the gas flowing through the gap G. The gas discharge hole 232 may discharge the gas in an oblique direction to facilitate rotation of the substrate supporting unit 22.

Accordingly, the substrate is rotated by rotation of the substrate supporting unit 22 and, simultaneously, revolved by rotation of the main body 21. As a result, the crystal may grow more uniformly. Also, since the substrate supporting unit 22 rotates with the predetermined gap G from the main body 21, frictional damage and deformation of those parts may be prevented, while achieving stable vapor-deposition.

The bottom surface of the substrate supporting unit 22 may be recessed in a shape corresponding to the mounting unit 23. Therefore, the bottom surface of the substrate supporting unit 22 may be recessed in the conical shape corresponding to the mounting unit 23. To be more specific, the bottom surface of the substrate supporting unit 22 may include a recessed portion 224 and a center point 225. Also, an inclined surface may be formed around the center point 225. Accordingly, the mounting unit 23 may be received in the substrate supporting unit 22.

According to the above configuration, even though the substrate supporting unit 22 being returned to the mounting unit 23 is seated on a wrong position which is a little deviated from the center of the mounting unit 23, the wrong position may be corrected. Also, since the substrate supporting unit 22 is separated from the mounting unit 23 by a predetermined interval by the gas discharged from the gas discharge hole 232, the position correction of the substrate supporting unit 22 may be more conveniently achieved. In other words, since the substrate supporting unit 22 and the mounting unit 23 have corresponding shapes to each other and since the substrate supporting unit 22 is floated by the gas, positioning of the substrate supporting unit 22 being returned may be more easily performed, accordingly reducing an error rate during returning of the substrate supporting unit 22.

The heat source 30 supplies heat to an inside of the reaction chamber 10. Specifically, the heat source 30 is disposed near the susceptor 20 to supply the susceptor 20 with the heat for heating the substrate. Any of an electric heater, a high frequency induction heater, an infrared radiation heater, and a laser heater may be used as the heat source 30.

The transfer unit 40 may include a grip portion 41 to grip the substrate supporting unit 22, and an extension portion 42 extending from the grip portion 41. The transfer unit 40 may be automatically controlled like a robot arm. The transfer unit 40 may transfer the substrate along with the substrate supporting unit 22 to the outside of the reaction chamber 10, or return the substrate supporting unit 22 separated from the substrate to the reaction chamber 10.

Hereinafter, an operation of the example embodiments will be described.

When the GaN-based epitaxial layer is grown and vapor-deposited on a surface of the substrate, an object of the vapor-deposition, that is, the substrate is placed on the substrate supporting unit 22.

In this case, the main body 21 may be rotated in one direction by a driving force of the rotational shaft 210. The substrate supporting unit 22 is rotated by the viscosity of the gas discharged through the gas discharge hole 232.

In addition, the reaction gas supply unit 12 may supply the reaction gas mixedly containing a source gas such as trimethylgallium (TMGa) and a carrier gas such as ammonia.

The heat source 30 may supply heat to the reaction chamber 10.

Accordingly, the reaction gas is brought into uniform contact with the surface of the substrate, thereby uniformly forming a thin film on which a nitride is grown, that is, the semiconductor epitaxial layer.

Next, the grip portion 41 of the transfer unit 40 may grip the substrate supporting unit 22 seated on the mounting unit 23 and transfer the substrate and the substrate supporting unit 22 together. Since the substrate supporting unit 22 is separated from the mounting unit 23 by the predetermined interval, the transfer unit 40 may transfer the substrate supporting unit 22 efficiently.

After the substrate supporting unit 22 is transferred to the outside of the reaction chamber 10, the substrate is separated from the substrate supporting unit 22.

Next, the substrate supporting unit 22 may be returned to the mounting unit 23. The mounting unit 23 is protruded whereas the substrate supporting unit 22 is recessed in a shape corresponding to the shape of the mounting unit 23. The substrate supporting unit 22 is floated by the gas discharged from the gas discharge hole 232. Therefore, even when the substrate supporting unit 22 is returned to a wrong position deviated from the center of the mounting 23, the wrong position of the substrate supporting unit 22 may be corrected.

Hereinafter, other example embodiments will be described. While configurations of only a substrate supporting unit and a mounting unit are distinctive, the other features of the present embodiments are the same as those of the previous embodiments and will not be repeatedly explained.

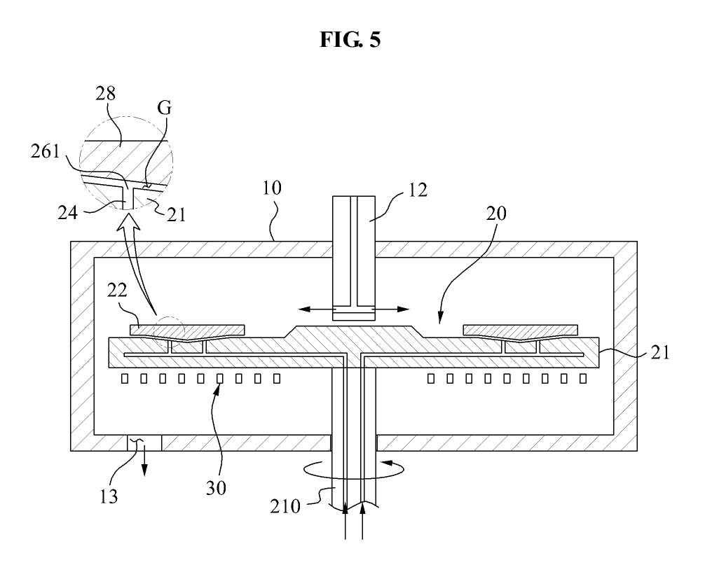

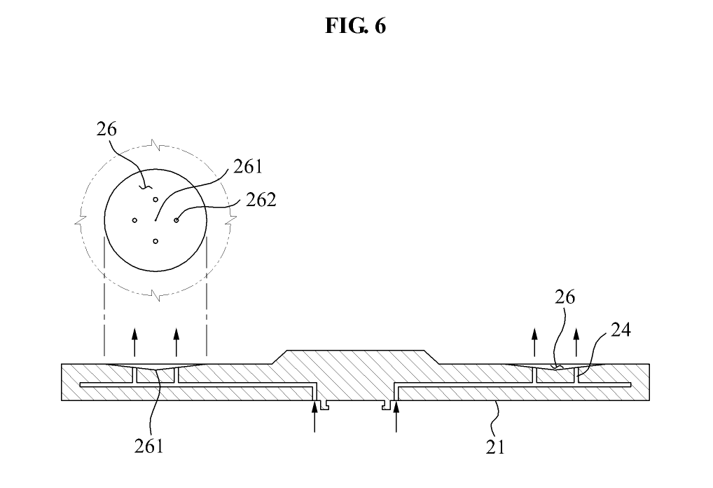

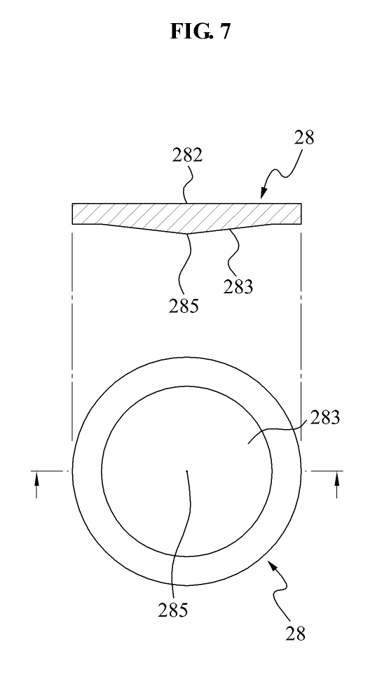

FIG. 5 illustrates a sectional view of a susceptor for a CVD apparatus, according to other example embodiments. FIG. 6 illustrates a sectional view of the susceptor shown in FIG. 5, where a substrate supporting unit is separated. FIG. 7 illustrates a bottom perspective view of the substrate supporting unit.

Referring to FIGS. 5 to 7, a mounting unit 26 of the present example embodiments may be recessed from an upper surface of the main body 21. For example, the mounting unit 26 may be recessed in a funnel shape tapered to have a wide upper portion and a narrow lower portion. According to this, a lowermost point 261 may be formed in a center of the mounting unit 26. An inclined surface may be formed around the lowermost point 261. The inclined surface may be inclined upward from the lowermost point 261 toward a periphery.

A gas discharge hole 262 may be formed on the mounting unit 26 to discharge gas. More specifically, the gas discharge hole 262 may be formed on the inclined surface of the mounting unit 26.

The substrate may be seated on an upper surface 282 of a substrate supporting unit 28 according to the present example embodiments. The upper surface 282 may be plane.

A bottom surface of the substrate supporting unit 28 may be protruded in a shape corresponding to the mounting unit 26. That is, the bottom surface may be protruded in a conical shape to be received in the mounting unit 26. More specifically, the bottom surface of the substrate supporting unit 28 may include a protruded portion 283 and a center point 285. Also, an inclined surface may be formed around the center point 285. According to this, the substrate supporting unit 28 may be received in the mounting unit 26.

Thus, since the substrate supporting unit 28 and the mounting unit 26 have corresponding shapes to each other and since the substrate supporting unit 28 is floated by the gas, positioning of the substrate supporting unit 28 being returned may be more easily performed, accordingly reducing an error rate during returning of the substrate supporting unit 28.

According to the example embodiments, when a substrate supporting unit is returned, accurate positioning of the substrate supporting unit may not be required.

In addition, the substrate supporting unit may be prevented from being deformed by friction with a pin. Therefore, vapor-deposition may be stably performed.

Although example embodiments have been shown and described, it would be appreciated by those skilled in the art that changes may be made in these example embodiments without departing from the principles and spirit of the disclosure, the scope of which is defined in the claims and their equivalents.

What is claimed is:

1. A susceptor comprising:
a main body configured to comprise a mounting unit having an uneven plane; and
a substrate supporting unit configured to be seated on the mounting unit,
wherein a bottom surface of the substrate supporting unit has a shape corresponding to a shape of the mounting unit, and the mounting unit comprises a gas discharge hole to discharge gas to the substrate supporting unit.

2. The susceptor of claim 1, wherein the mounting unit comprises a conically protruded portion or recessed portion.

3. The susceptor of claim 2, wherein the mounting unit comprises an inclined surface, and the gas discharge hole is formed on the inclined surface.

4. The susceptor of claim 1, wherein the substrate supporting unit is separated from the main body by the gas.

5. The susceptor of claim 4, wherein a gap is formed between the substrate supporting unit and the main body to allow flow of the gas.

6. The susceptor of claim 1, wherein
the gas is discharged in an oblique direction from the gas discharge hole, and
the substrate supporting unit rotates due to viscosity of the gas.

7. The susceptor of claim 1, wherein the gas is nitrogen or hydrogen.

8. An apparatus for chemical vapor deposition (CVD), comprising:
a reaction chamber configured to be supplied with a reaction gas; and
a susceptor configured to comprise a main body rotatively mounted to the reaction chamber and a substrate supporting unit removably connected to the main body,
wherein the main body is provided with a mounting unit comprising an inclined surface, and the substrate supporting unit is provided with an inclined surface corresponding to the inclined surface of the mounting unit.

9. The apparatus of claim 8, further comprising:
a gas supply pipe provided to the main body to supply gas for floating the substrate supporting unit;
a heat source to supply heat to the reaction chamber; and
a transfer unit to transfer the substrate supporting unit.

10. The apparatus of claim 8, wherein the mounting unit comprises a protruding portion and the substrate supporting unit comprises a recessed portion.

11. The apparatus of claim 10, wherein the mounting unit has a conical shape.

12. The apparatus of claim 8, wherein
the mounting unit comprises a recessed portion, and
the substrate supporting unit comprises a protruded portion.

13. The apparatus of claim 12, wherein the protruded portion has a conical shape.

14. The apparatus of claim 9, wherein the inclined surface of the mounting unit comprises a gas discharge hole fluidly communicating the gas supply pipe.

15. The apparatus of claim 9, wherein the substrate supporting unit is separated from the main body by the gas.

16. The apparatus of claim 8, wherein the susceptor is composed of carbon coated with silicon carbide (SiC).
